(19) United States
(12) Patent Application Publication
(10) Pub. No.: US 2017/0338325 A1
(43) Pub. Date: Nov. 23, 2017

(54) METHOD, APPARATUS AND SYSTEM FOR PROVIDING NITRIDE CAP LAYER IN REPLACEMENT METAL GATE STRUCTURE

(71) Applicant: GLOBALFOUNDRIES INC., Grand Cayman (KY)

(72) Inventors: Huy Cao, Rexford, NY (US); Chih-Chiang Chang, Clifton Park, NY (US); Katsunori Onishi, Somers, NY (US); Songkram Srivathanakul, Waterford, NY (US)

(73) Assignee: GLOBALFOUNDRIES INC., Grand Cayman (KY)

(21) Appl. No.: 15/160,845

(22) Filed: May 20, 2016

(51) Int. Cl. H01L 29/66; H01L 21/3105; H01L 21/02; H01L 27/088; H01L 21/8234

(52) U.S. Cl. CPC H01L 29/66545; H01L 27/088; H01L 21/823437; H01L 21/02274; H01L 21/31055; H01L 21/02348; H01L 21/823418

(57) ABSTRACT

We disclose a semiconductor device, comprising a semiconductor substrate; at least one gate structure disposed above the semiconductor substrate, wherein the gate structure comprises a gate structure cavity partially filled with at least one metal layer; and an ultraviolet (UV) cured high density plasma (HDP) nitride cap layer in the gate structure cavity above the at least one metal layer. We also disclose at least one method and at least one system by which the semiconductor device may be formed. The UV cured HDP nitride cap layer may be substantially free of voids or seams, and as a result, the semiconductor device may have a reduced Vt shift relative to comparable semiconductor devices known in the art.

### FIELD OF THE INVENTION

Generally, the present disclosure relates to the manufacture of sophisticated semiconductor devices, and, more specifically, to providing improved nitride cap layers in replacement metal gate structures comprising self-aligned contacts.

### DESCRIPTION OF THE RELATED ART

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

In an ongoing effort to reduce process complexity, workers have introduced self-aligned contacts in the formation of metal-oxide-semiconductor field-effect transistors (MOSFETs). However, self-aligned contacts are challenging to apply to 10 nm and/or 7 nm processes expected to be introduced by about the year 2020. Nitride cap layers have been used in self-aligned contacts, but known nitride cap layers produced by plasma-enhanced chemical vapor deposition (PECVD) have had a number of undesirable properties. For example, as shown in FIG. 2, known nitride cap layers 170 tend to have voids or seams 175. The presence of voids or seams 175 may impair the Vt of a semiconductor device, and hence, is undesirable.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to a semiconductor device comprising a semiconductor substrate; at least one gate structure disposed above the semiconductor substrate, wherein the gate structure comprises a gate structure cavity partially filled with at least one metal layer; and an ultraviolet (UV) cured high density plasma (HDP) nitride cap layer in the gate structure cavity above the at least one metal layer. We also disclose at least one method and at least one system by which the semiconductor device may be formed. The UV cured HDP nitride cap layer may be substantially free of voids or seams, and as a result, the semiconductor device may have a reduced Vt shift relative to comparable semiconductor devices known in the art.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a stylized depiction of a semiconductor device after a first stage of processing, in accordance with embodiments herein;

FIG. 2 illustrates a stylized depiction of a prior art semiconductor device;

FIG. 3 illustrates a stylized depiction of a semiconductor device after a second stage of processing, in accordance with embodiments herein;

FIG. 4 illustrates a stylized depiction of a semiconductor device after a third stage of processing, in accordance with embodiments herein;

FIG. 5 illustrates a stylized depiction of a semiconductor device after a fourth stage of processing, in accordance with embodiments herein;

FIG. 6 illustrates a stylized depiction of a system for fabricating a semiconductor device, in accordance with some embodiments herein; and

FIG. 7 depicts a flowchart of a method, in accordance with some embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for utilizing a nitride cap process for fabricating self-aligned contacts. A high density plasma process may be used to form a nitride cap feature above a metal layer in a gate structure cavity. The nitride cap process of embodiments herein provide for satisfying self-aligned contact requirements, reducing nitride erosion during processing, minimizing the formation of voids or seams in the nitride cap, and reducing Vt shifts in semiconductor devices, thereby imparting improved device performance.

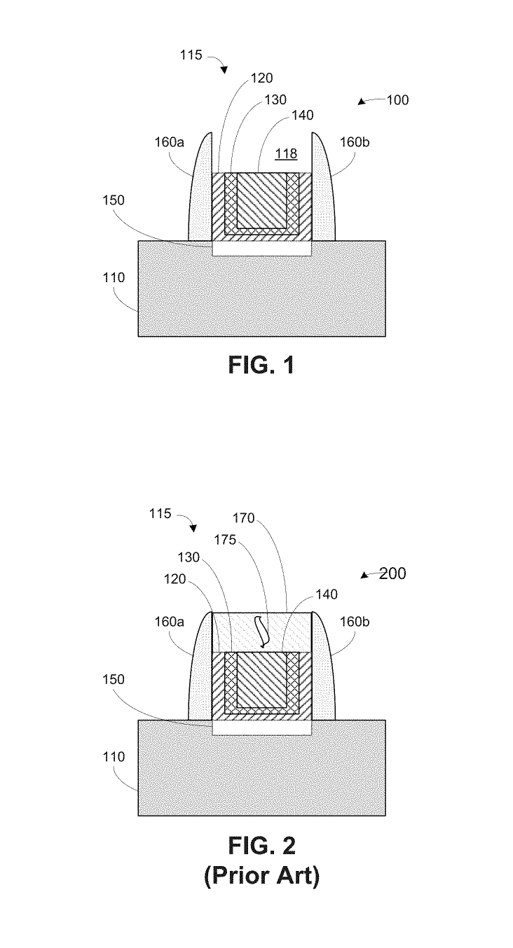

FIG. 1 illustrates a stylized depiction of a semiconductor device provided to a first stage of processing, in accordance with embodiments herein. The structure 100 may comprise a semiconductor substrate 110 and a gate structure 115.

Any substrate material may be used in the semiconductor substrate 110. In one embodiment, the semiconductor substrate 110 comprises bulk silicon.

The gate structure 115 may be prepared according to known techniques and comprise features known to the person of ordinary skill in the art. For example, the gate structure 115 may comprise a gate structure cavity 118, defined by spacers 160a and 160b and a gate oxide 150. The gate structure cavity 118 may be partially filled with at least one metal layer 140. In one embodiment, the at least one metal layer 140 may comprise tungsten. The gate structure cavity 118 may also be partially filled with a titanium liner 120 and a titanium nitride layer 130.

Although only one gate structure 115 and no other structures of semiconductor device 100 are depicted in FIGS. 1-5 for the sake of brevity, the person of ordinary skill in the art will understand that additional gate structures 115 and/or other structures that may be included in semiconductor device 100 may be present in a semiconductor device 100 according to the present disclosure despite being omitted from the figures.

For example, the semiconductor device 100 may comprise a plurality of gate structures 115, wherein the pitch between gate structures 115 may be 14 nm, 10 nm, or 7 nm. In one embodiment, the pitch may be 10 nm or 7 nm.

FIG. 2 depicts a semiconductor device 200 known in the art. The semiconductor device 200 has received a nitride cap 170 deposited by PECVD, with excess nitride removed by CMP or the like. The nitride cap 170 deposited by PECVD contains a seam or void 175.

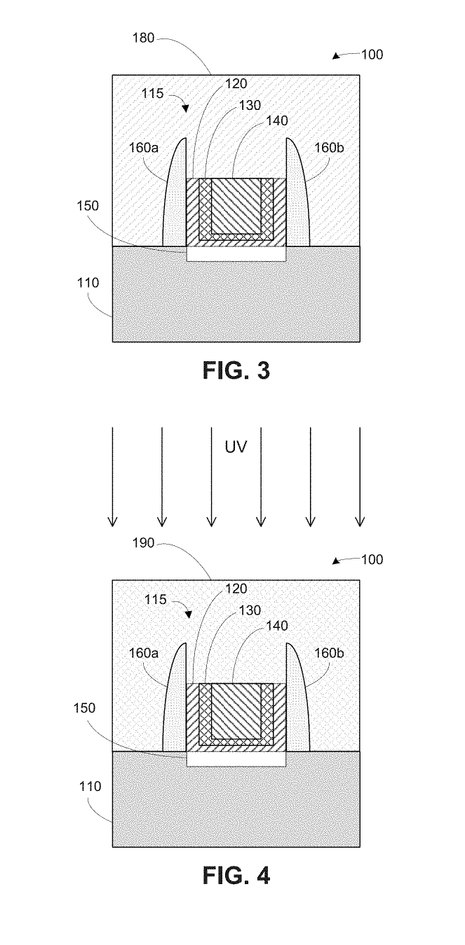

Turning now to FIG. 3, a stylized depiction of the semiconductor device 100 after a second stage of processing, in accordance with embodiments herein, is presented. In the second stage of processing, a nitride layer 180 is deposited by a high density plasma (HDP) process. HDP deposition techniques known in the art may be used by the person of ordinary skill in the art having the benefit of the present disclosure.

FIG. 4 presents a stylized depiction of the semiconductor device 100 after a third stage of processing in accordance with embodiments herein. As illustrated, an ultraviolet (UV) cure of the nitride cap layer 180 may be performed. The UV cure produces a cured nitride cap layer 190. UV cure techniques known in the art may be used by the person of ordinary skill in the art having the benefit of the present disclosure.

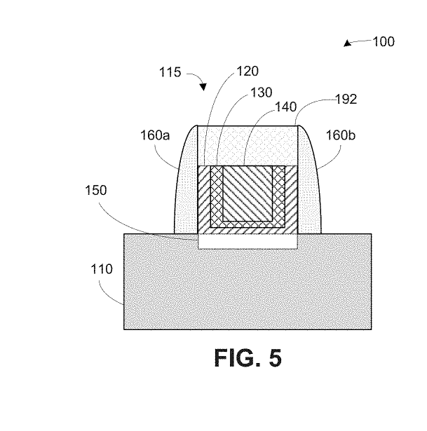

FIG. 5 presents a stylized depiction of the semiconductor device 100 after a fourth stage of processing, in accordance with embodiments herein. In the fourth stage of processing, excess cured nitride cap layer 190 above the top of and/or outside of gate structure 115 is removed by CMP and/or similar techniques, thereby yielding a cured nitride cap 192. As depicted, a top of the cured nitride cap 192 may be at substantially the same height as a top of the gate structure 115. In other embodiments (not shown), a top of the cured nitride cap 192 may be below or above a top of the gate structure 115.

The present inventors have found that the cured nitride cap 192 may have one or more desirable properties. For example, the cured nitride cap 192 may be substantially free of voids or seams. For another example, the cured nitride cap 192 may have a reduced hydrogen content compared to a nitride cap formed by plasma-enhanced chemical vapor deposition (PECVD). A reduced hydrogen content in the cured nitride cap 192 may lead to a reduced Vt shift for a semiconductor device comprising the cured nitride cap 192 relative to a semiconductor device comprising a nitride cap formed by PECVD. Alternatively or in addition, the cured nitride cap 192 may have an improved scratch resistance compared to a nitride cap formed by PECVD. Alternatively or in addition, the cured nitride cap 192 may have an improved chemical resistance (e.g., improved resistance to wet etching and/or chemical mechanical polishing (CMP) solutions) compared to a nitride cap formed by PECVD. Further, the cured nitride cap 192 may have reduced compression and/or increased tensile strength compared to a nitride cap formed by PECVD. Reduced compression and/or increased tensile strength may impart beneficial properties to a PFET device comprising the gate structure 115 and cured nitride cap 192.

The semiconductor device depicted in FIG. 5 may be subjected to further processing steps (not shown), such as forming a plurality of sources and drains, wherein one source and one drain are adjacent to each gate structure, and forming a plurality of contacts, wherein one contact is disposed above and in electrical connection with one source or drain.

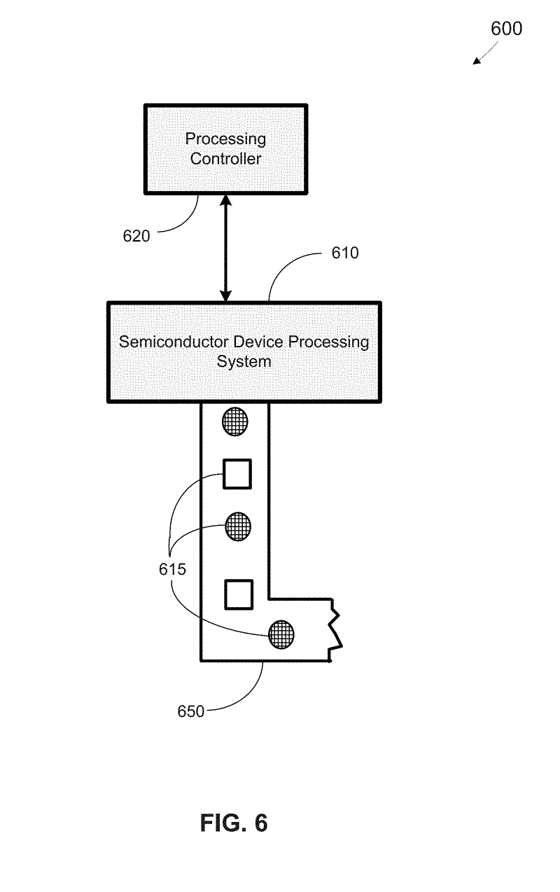

Turning now to FIG. 6, a stylized depiction of a system for fabricating a semiconductor device comprising the cured nitride cap layer 140b, in accordance with some embodiments herein, is illustrated. The semiconductor device processing system 610 may comprise various processing stations, such as etch process stations, photolithography process stations, CMP process stations, HDP deposition stations, UV cure stations, etc. One or more of the processing steps performed by the processing system 610 may be controlled by the processing controller 620. The processing controller 620 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device processing system 610 may produce integrated circuits on a medium, such as silicon wafers. The production of integrated circuits by the device processing system 610 may be based upon the circuit designs provided by the processing controller 620. The semiconductor device processing system 610 may provide processed integrated circuits/devices 615 on a transport mechanism 650, such as a conveyor system. In some embodiments, the conveyor system may be sophisticated clean room transport systems that are capable of transporting semiconductor wafers. In one embodiment, the semiconductor device processing system 610 may comprise a plurality of processing steps, e.g., the 1^{st} process step, the 2^{nd} process set, etc., as described above.

In some embodiments, the items 615 may represent individual wafers, and in other embodiments, the items 615 may represent a group of semiconductor wafers, e.g., a “lot” of semiconductor wafers. The integrated circuit or device 615 may be a transistor, a capacitor, a resistor, a memory cell, a processor, and/or the like.

The system 600 may be capable of manufacturing various products involving various technologies. For example, the system 600 may manufacture devices of CMOS technology, Flash technology, BiCMOS technology, power devices, controllers, processors, memory devices (e.g., DRAM devices), NAND memory devices, and/or various other semiconductor technologies.

Although in some examples, circuits herein were described in terms of MOSFET transistors for consistency and ease of illustration, the person of ordinary skill in the art would appreciate that concepts described herein may also apply to other devices and remain within the scope of embodiments herein.

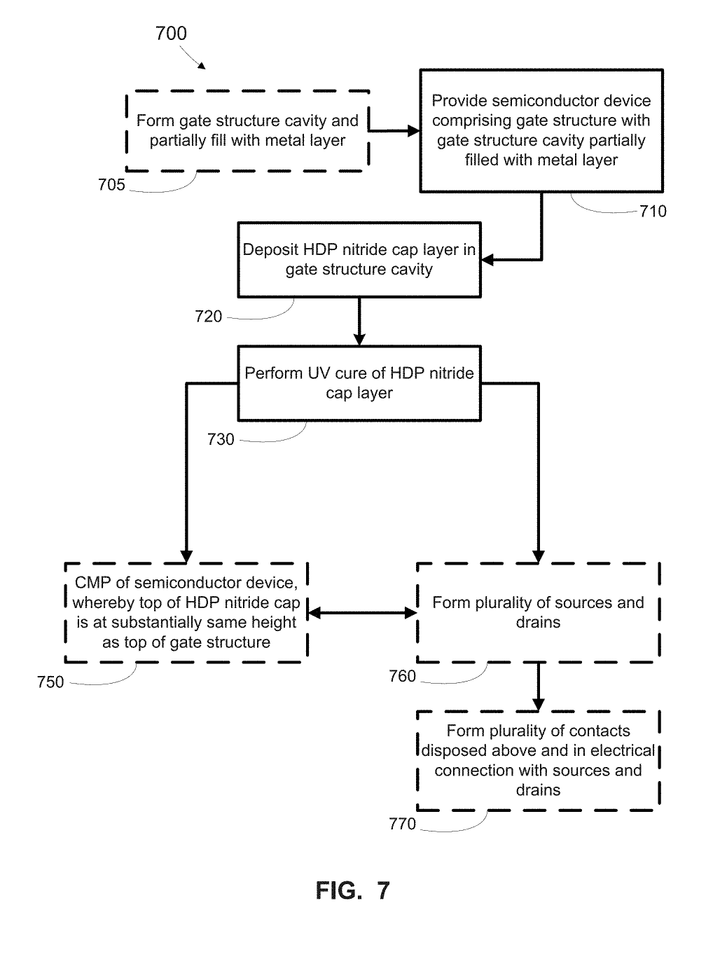

Turning to FIG. 7, a flowchart of a method 700, in accordance with embodiments herein, is shown. The method 700 may comprise providing (at 710) a semiconductor device comprising at least one gate structure disposed above a semiconductor substrate, wherein the gate structure comprises a gate structure cavity partially filled with at least one metal layer. The structure may comprise other features, as discussed above. For example, the pitch between adjacent gate structures may be 10 nm or 7 nm.

In one embodiment, the method 700 may comprise (at 705) forming the gate structure cavity; depositing at least one metal layer in and above the gate structure cavity; chemical mechanical polishing (CMP) the semiconductor device, whereby a top of the at least one metal layer is at substantially the same height as a top of the gate structure; and recessing the at least one metal layer, whereby the gate structure cavity is partially filled with the at least one metal layer. Upon completion of forming etc. (at 705), the resulting semiconductor device may be provided (at 710) for further aspects of the method 700.

The method 700 may also comprise depositing (at 720) a high density plasma (HDP) nitride cap layer in the gate structure cavity. Thereafter, the method 700 may comprise performing (at 730) an ultraviolet (UV) cure of the HDP nitride cap layer.

In some embodiments, depositing the HDP nitride cap layer (at 720) may further comprise depositing the HDP nitride cap layer above and outside the gate structure cavity, and the method 700 may further comprise chemical mechanical polishing (CMP) (at 750) the semiconductor device, to yield an HDP nitride cap with a top at substantially the same height as a top of the gate structure.

The UV cured HDP nitride cap may have one or more of reduced hydrogen content, improved scratch resistance, improved chemical resistance, reduced compression, and/or increased tensile strength relative to a nitride cap formed by PECVD. Alternatively or in addition, the UV cured HDP nitride cap may be substantially free of voids and seams.

The method 700 may further comprise forming (at 760) a plurality of sources and drains, wherein one source and one drain are adjacent to each gate structure, and forming (at 770) a plurality of contacts, wherein one contact is disposed above and in electrical connection with one source or drain.

The methods described above may be governed by instructions that are stored in a non-transitory computer readable storage medium and that are executed by, e.g., a processor in a computing device. Each of the operations described herein may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method, comprising:
providing a semiconductor device comprising at least one gate structure disposed above a semiconductor substrate, wherein the gate structure comprises a gate structure cavity partially filled with at least one metal layer;
depositing a high density plasma (HDP) nitride cap layer in the gate structure cavity above the metal layer; and
performing an ultraviolet (UV) cure of the nitride cap layer.

2. The method of claim 1, wherein depositing the HDP nitride cap layer further comprises depositing the HDP nitride cap layer above and outside the gate structure cavity.

3. The method of claim 2, further comprising chemical mechanical polishing (CMP) the semiconductor device, whereby a top of the HDP nitride cap layer is at substantially the same height as a top of the gate structure.

4. The method of claim 1, wherein the pitch between adjacent gate structures is 10 nm or 7 nm.

5. The method of gate 1, further comprising forming the gate structure cavity; depositing at least one metal layer in and above the gate structure cavity; chemical mechanical polishing (CMP) the semiconductor device, whereby a top of the at least one metal layer is at substantially the same height as a top of the gate structure; and recessing the at least one metal layer, whereby the gate structure cavity is partially filled with the at least one metal layer.

6. The method of claim 1, further comprising forming a plurality of sources and drains, wherein one source and one drain are adjacent to each gate structure.

7. The method of claim 6, further comprising forming a plurality of contacts, wherein one contact is disposed above and in electrical connection with one source or drain.

8. The method of claim 1, wherein performing the UV cure renders the HDP nitride cap layer substantially free of voids or seams.

9. A semiconductor device, comprising:
a semiconductor substrate;
at least one gate structure disposed above the semiconductor substrate, wherein the gate structure comprises a gate structure cavity partially filled with at least one metal layer; and
an ultraviolet (UV) cured high density plasma (HDP) nitride cap in the gate structure cavity above the at least one metal layer.

10. The semiconductor device of claim 9, wherein a top of the cured HDP nitride cap is at substantially the same height as a top of the gate structure.

11. The semiconductor device of claim 9, wherein the pitch between adjacent gate structures is 10 nm or 7 nm.

12. The semiconductor device of claim 9, further comprising a plurality of sources and drains, wherein one source and one drain are adjacent to each gate structure.

13. The semiconductor device of claim 12, further comprising a plurality of contacts, wherein one contact is disposed above and in electrical connection with one source or drain.

14. The semiconductor device of claim 9, wherein the UV cured HDP nitride cap is substantially free of voids or seams.

15. A system, comprising:
a process controller, configured to provide an instruction set for manufacture of a semiconductor device to a manufacturing system; and
the manufacturing system, configured to manufacture the semiconductor device according to the instruction set;
wherein the instruction set comprises instructions to:
provide a semiconductor device comprising at least one gate structure disposed above a semiconductor substrate, wherein the gate structure comprises a gate structure cavity partially filled with at least one metal layer;
deposit a high density plasma (HDP) nitride cap layer in the gate structure cavity above the metal layer; and
perform an ultraviolet (UV) cure of the HDP nitride cap layer.

16. The system of claim 15, wherein the instruction set further comprises instructions to chemical mechanical polish (CMP) the semiconductor device, whereby a top of a HDP nitride cap is at substantially the same height as a top of the gate structure.

17. The system of claim 15, wherein the instruction set further comprises instructions to provide adjacent gate structures with a pitch of 10 nm or 7 nm.

18. The system of claim 17, wherein the instruction set further comprises instructions to provide a plurality of sources and drains in the structure, wherein one source and one drain are adjacent to each gate structure.

19. The system of claim 18, wherein the instruction set further comprises instructions to provide a plurality of contacts, wherein one contact is disposed above and in electrical connection with one source or drain.
